(19) United States
(12) Patent Application Publication
(10) Pub. No.: US 2002/0157053 A1
(43) Pub. Date: Oct. 24, 2002

(54) Semiconductor test system with time critical sequence generation using general purpose operating system

(76) Inventors: Leon Lee Chen, Santa Clara, CA (US); James Alan Turnquist, Santa Clara, CA (US)

Correspondence Address: MURAMATSU & ASSOCIATES, Suite 225, 7700 Irvine Center Drive, Irvine, CA, 92618, US

(21) Appl. No.: 09/839,013

(22) Filed: Apr. 21, 2001

(51) Int. Cl. G06F 11/00; G01R 31/28

(52) U.S. Cl. 714/744

(57) ABSTRACT

A semiconductor test system is capable of time critical sequence generation using a general purpose operating system. The semiconductor test system includes a tester hardware for providing power sources and test patterns to a device under test, a host computer operated by a general purpose operating system, a configuration software for computing configuration data and timing data based on a test program, a device driver for providing a power trigger and a signal trigger to the tester hardware, and a hardware timer for producing an interrupt signal. The device driver causes to start the test pattern and to deactivate the power sources upon receiving the interrupt signal.

### FIELD OF THE INVENTION

This invention relates to a semiconductor test system for testing semiconductor devices such as ICs and LSIs, and more particularly, to a semiconductor test system capable of time critical sequence generation using a general purpose operating system.

### BACKGROUND OF THE INVENTION

In testing semiconductor devices such as ICs and LSIs by a semiconductor test system, such as an IC tester, a semiconductor IC device to be tested is provided with test signals (test patterns) produced by an IC tester at its appropriate tester pins at predetermined test timings. The IC tester receives output signals from the IC device under test in response to the test signals. The output signals are strobed (sampled) by strobe signals at predetermined timings to be compared with expected output data to determine whether the IC device functions correctly.

In such a semiconductor testing environment, as part of a test, it is necessary for the system to control a sequence of operations on the tester, device under test (DUT), and associated equipment. As an example, a sequence of operations occurring as part of a functional test for a logic device under test (DUT) is shown in the timing diagrams of FIGS. 1A-1D.

In this example, the test system provides one or more power supplies (sources) to the DUT. The start-up events for two power supplies are, for example, desired at the times S1 and S2 as shown in FIGS. 1A and 1B. Signal lines of the DUT must be initialized at the time Si in FIG. 1C. The digital test pattern is applied to the DUT, the beginning of the test pattern is shown as time St in FIG. 1D. In reality, the digital test pattern may be as long as several hundred kilobytes or several megabytes of vectors.

The digital test pattern for an intended test plan is completed either by the detection of failure in the output of DUT or exhaustion of the test pattern. The ending of the pattern is shown at time Et in FIG. 1D. After ending the test pattern, the power sources are removed (deactivated) from the DUT. The desired times for these ending events are shown at E2 and E1 in FIGS. 1A and 1B. The above noted sequence may be repeated for the DUT for conducting different kinds of logic tests.

In practice, the test engineer will specify the time of the events S1, S2, Si, relative to the start of the test pattern at time St, as part of the test application program. In a similar fashion, the ending events E2 and E1, which turn off the DUT power supplies, are specified relative to the pattern ending time Et.

For the results of a logic test to be valid, the test system must control the timings of the tester, DUT, and associated equipment, in an accurate and repeatable fashion. Significant error or variation in the sequence timing may cause the test to be invalid, the test to give inconsistent results, or cause damage to the DUT. The required timing resolution of the specified events, for example, S1, S2, Si, etc., is typically 1 millisecond, with a variability of ±100 microseconds.

Current tester systems typically use a general-purpose operating system, such as UNIX or Microsoft Windows so that the user may run a variety of testing applications and engineering software. These may be provided by the tester vendor, the customer, or by third parties. These general-purpose operating system platforms, however, do not generally provide mechanisms by which software may perform time critical functions in a repeatable fashion. Using only a general purpose operating system typically results timing variability of 0 to 10 milliseconds which is not controllable by the user.

In other words, the timing of the testing events will not occur at the desired times. In the timing diagrams in FIGS. 2A and 2B, the timings S1 and S2 occur earlier than that intended in FIGS. 1A and 1B, and the timings E2 and E1 occur later than that intended. This causes errors in the testing and makes the test results unreliable.

In order to solve this problem, a common practice is to add the use a specialized “real time” operating system to allow the test system software to support accurate sequence control of the semiconductor test system (IC tester) and DUT (“Advantest T6682 Viewpoint architecture”, Advantest, 1998). This generally runs on an additional processor(s). In some cases, such a real time operating system may also run on the same processor(s) as the general-purpose operating system. The use of the real time operating system usually allows timing resolution and repeatability that are between 100 to 1000 microseconds.

However, the use of this additional operating system results in a configuration that has a non-homogeneous operating systems running on multiple processors. This increases overall complexity in such as developing test programs and decreases flexibility in such as using application software. Consequently, this approach increases an overall test cost.

An alternative prior art is to use a single real time operating system that supports the application programs and allows the tester system software to satisfy the sequencing requirements (“Advantest T6682 Viewpoint architecture”, Advantest, 1998). This provides the simplicity and performance of a homogeneous environment, and provides high resolution and repeatability. Unfortunately, this solution tends to constrain the design and implementation of the application programs, since real time operating systems generally provide fewer services and support libraries than general purpose operating systems.

Therefore, there is a need in the industry of an improved semiconductor test system which overcomes the shortcomings discussed above.

### SUMMARY OF THE INVENTION

It is, therefore, an object of the present invention to provide a semiconductor test system for testing semiconductor devices which is capable of establishing timing critical sequence using a general purpose operating system.

It is another object of the present invention to provide a semiconductor test system configured with a combination of custom hardware and software components to achieve the timing critical sequence in activating and deactivating various parameters for each test.

It is a further object of the present invention to provide a semiconductor test system for testing semiconductor devices which is capable of establishing timing relationships among power sources, reference voltages, and test pattern generation with high timing resolution and accuracy.

In the present invention, the semiconductor test system includes a tester hardware for providing power sources to power source pins of a semiconductor device under test (DUT) and applying a test pattern to an input pin of the DUT and evaluating an output signal of the DUT, and a host computer operated by a general purpose operating system for controlling an overall operation of the semiconductor test system based on a test program. The test system further includes a configuration software for computing configuration data indicating configuration of the power sources for DUT and reference voltages of the test pattern and timing data indicating timings of activating and deactivating the power sources, reference voltages and test pattern. The configuration software computes the configuration data and timing data based on the test program prior to testing the DUT. The test system further includes a device driver for providing a power trigger and a signal trigger to the tester hardware to trigger the timings of activating and deactivating the power sources and the reference voltages in the hardware tester, and a hardware timer for producing an interrupt signal after a predetermined time defined by the device driver and sending the interrupt signal to the device driver through the host computer. The device driver causes to start the test pattern upon receiving the interrupt signal from the hardware timer and to deactivate the power sources to the DUT upon receiving the interrupt signal from the hardware timer.

In the present invention, the device driver causes to stop the test pattern upon receiving an end of test signal generated by the tester hardware through the host computer and triggers the hardware timer to produce an interrupt signal after a specified time interval and causes to deactivate the power sources to the DUT upon receiving the interrupt signal from the hardware timer.

The device driver is a software configured to respond to the interrupt signal through the host computer in a timely fashion with a minimal time latency and with high priority. The device driver is designed to respond to the interrupt signal generated by the hardware timer or an interrupt signal generated by the tester hardware.

The tester hardware includes a hardware control circuitry for formatting the test pattern based on the reference voltages defined by the configuration data from the configuration software and for forming the power sources for the DUT defined by the configuration data from the configuration software. The tester hardware further includes a comparator for comparing the output signal of the DUT with an expected signal and producing a failure signal when detecting mismatch between the output signal and the expected signal, and an end of test logic for producing an end of test signal when receiving the failure signal from the comparator.

According to the present invention, the semiconductor test system is able to produce timing critical test sequence without using a specialized real time operating system. Since the semiconductor test system uses a general purpose operating system, flexibility, serviceability and abundance of application software are available. The semiconductor test system achieves the timing critical sequence in activating and deactivating various parameters for each test by incorporating the combination of custom hardware and software.

### BRIEF DESCRIPTION OF THE DRAWINGS

FIGS. 1A-1D are timing diagrams showing intended timing relationships in applying power sources and a test pattern to a semiconductor device under test.

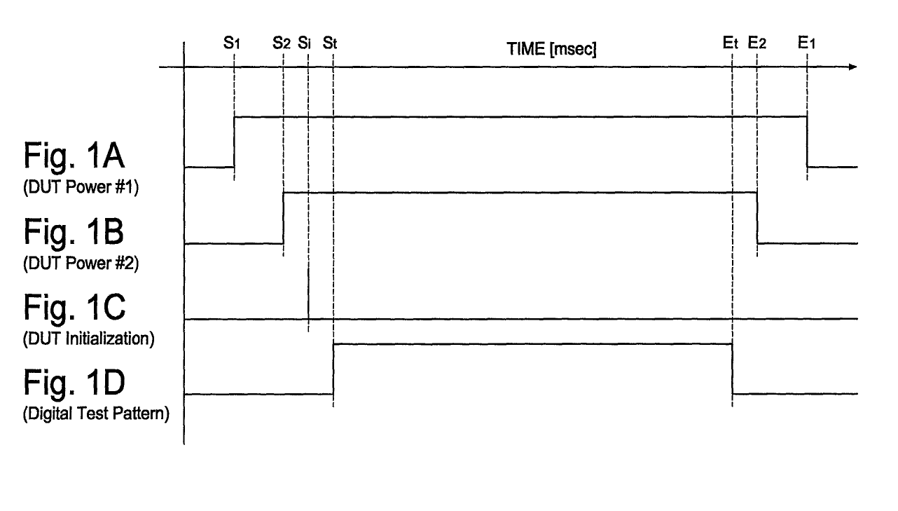

FIGS. 2A-2D are timing diagrams showing incorrect timing relationships in applying power sources and a test pattern to a semiconductor device under test.

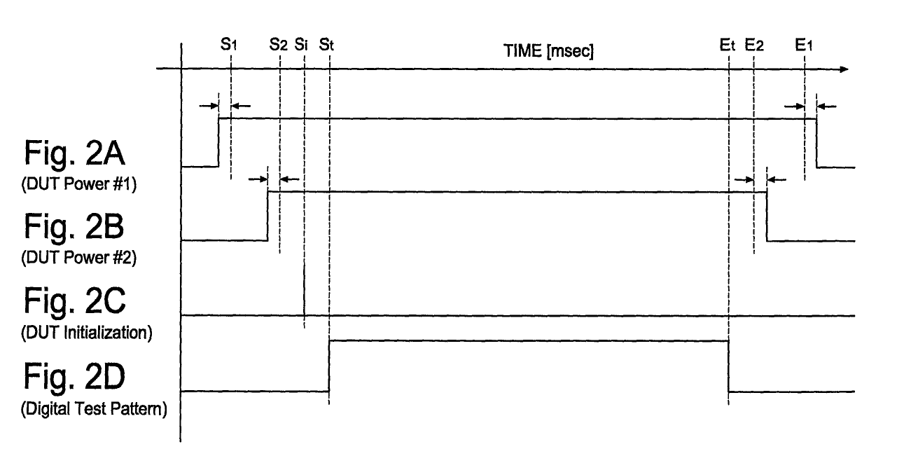

FIG. 3 is a block diagram showing an overall configuration of the semiconductor test system of the present invention which is capable of time critical sequence generation using a general purpose operating system.

FIG. 4 is a schematic block diagram showing an example of configuration in the hardware timer incorporated in the semiconductor test system of FIG. 3.

FIG. 5 is a schematic block diagram showing an example of configuration in the tester hardware including the hardware control circuitry incorporated in the semiconductor test system of FIG. 3.

FIG. 6 is a schematic diagram showing an example of configuration in the device driver incorporated in the semiconductor test system of FIG. 3.

FIG. 7 is a flow chart showing an example of operation for test sequence generation in the semiconductor test system of the present invention.

### DETAILED DESCRIPTION OF THE PREFERRED EMBODIMENT

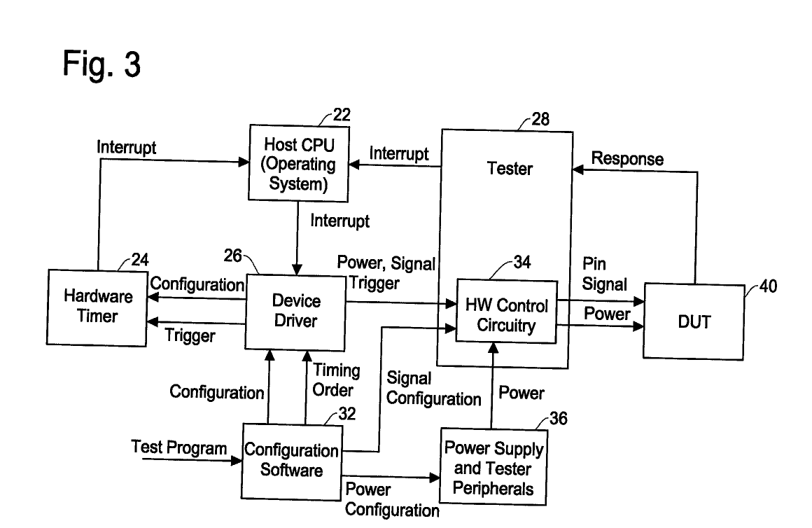

The semiconductor test system of the present invention will be described with reference to FIGS. 3-7. While the present invention will be described in conjunction with the preferred embodiments, it will be understood that they are not intended to limit the invention to these embodiments. On the contrary, the invention is intended to cover alternatives, modifications and equivalents, which may be included within the spirit and scope of the invention as defined by the appended claims.

The present invention uses a combination of custom hardware and software components to achieve the required capabilities. An overview of the hardware and software design includes a hardware programmable timer which produces interrupts on the host system, a tester hardware control circuitry, configuration software that is not time critical which precomputes hardware configurations and switching operations, and software “device driver” which is time critical, responds to the hardware programmable timer and tester interrupts, and controls the above hardware to indirectly configure the test equipment.

An example of overall configuration of the semiconductor test system is shown in the block diagram of FIG. 3 which includes the hardware and software components mentioned above. In the example of FIG. 3, the semiconductor test system is configured by a tester hardware 28 and a power supply and tester peripherals 36. The tester hardware 28 includes a hardware control circuitry (pin electronics) 34 that allows high speed direct and indirect changes to tester signal and power lines.

The power supply and tester peripherals 36 provide, for example, power sources to the hardware control circuitry 34 to be supplied to a semiconductor device under test (DUT) 40. The power supply and tester peripherals 36 also provide reference voltages to the hardware control circuitry 34 to form prescribed amplitudes of the test signal (pattern) to be supplied to the DUT 40. An overall operation of the semiconductor test system is controlled by a host computer 22 having an general purpose operating system. The DUT 40 is connected to the tester hardware 28 through the hardware control circuitry 34.

The semiconductor test system is further provided with a hardware programmable timer 24 which produces interrupts on the host computer 22 (general purpose operating system), a configuration software 32 which receives a test program and precomputes hardware configurations and switching operations that will achieve the desired sequences for starting and ending one or more tests, and a device driver 26 which is a time critical software to respond to the hardware programmable timer 24 and tester interrupts and controls the above hardware (tester hardware 28, hardware control circuitry 34, and hardware timer 24) to indirectly configure the test equipment. The host computer 22 is operated by the general purpose operating system such as UNIX, Windows, Window NT, Linux and the like. The host computer 22 controls an overall operation of the semiconductor test system based on the test program.

As a practical matter, due to computational, timing, and other resource constraints, the host computer 22 (general-purpose operating system) typically forbids complex or time consuming decision making at the device driver 26. Thus, these decision makings are precomputed or preconfigured whenever possible by the configuration software 32 and/or handled via the tester hardware 28. Namely, based on the test program from the host computer, the configuration software 32 precomputes the hardware configurations and switching operations that will achieve the initialization of power supply and pin signal. The precomputed data is transmitted to the device driver 26 and the hardware control circuitry 34 for execution.

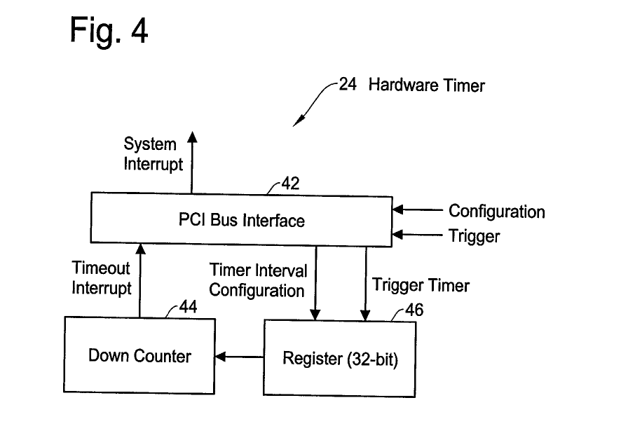

FIG. 4 shows an example of detailed diagram of the hardware timer 24. In this particular case, the hardware timer 24 is configured by a bus interface 42 such as a PCI bus interface, a register 46, and a down counter 44. An example of hardware timer has a 32-bit length with 0.5 MHz resolution. The register 46 is loaded with a precomputed value from the device driver 26 formed of, for example, 32-bit data, via a write operation. At the appropriate time, the hardware timer 24 is triggered by a trigger signal from the device driver through an additional write operation. This causes the hardware timer 24 to free-run, i.e., to down count a clock signal by the down counter 44. The down counter 44 produces an interrupt signal when reaching the precomputed value from the register 46, which interrupts the test system after the programmed interval using the PCI bus interrupt.

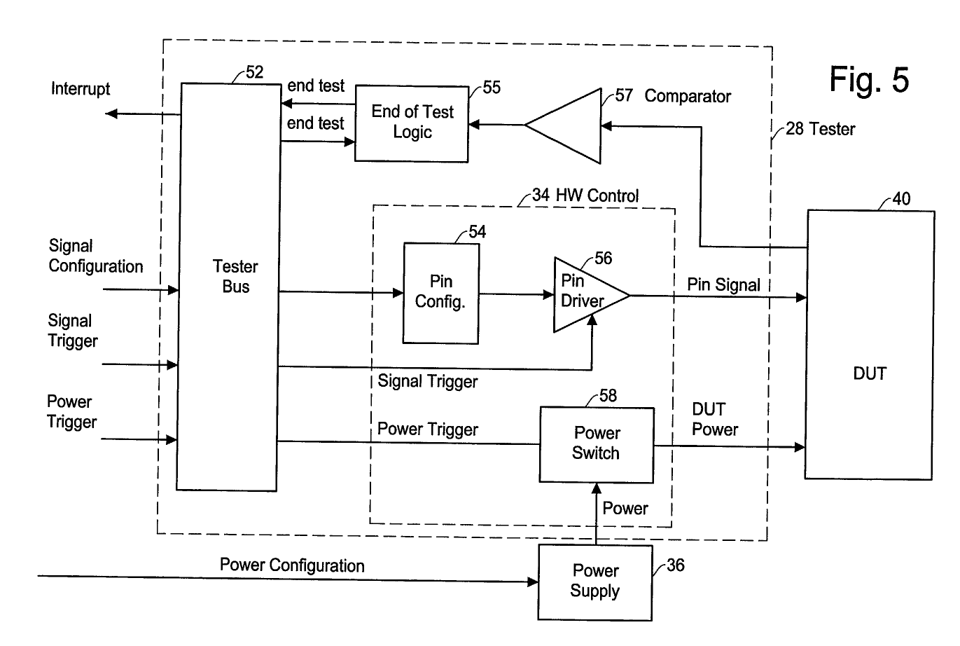

FIG. 5 shows an example of hardware circuitry in the tester hardware 28 which includes the hardware control circuitry 34, a tester bus 52, a comparator 57, and an end of test logic 55. The hardware control circuitry 34 is configured with a pin configuration register 54, a pin driver electronics 56, and a power switch 58. An actual test system includes a large number of these components depending upon the anticipated number of pins of semiconductor devices to be tested. The tester hardware 28 receives, through the tester bus 52, pin configuration data from the configuration software 32, and a signal trigger and a power trigger from the device driver 26.

The pin driver electronics 56 produces a pin signal (test signal or clock signal) which is supplied to a device input pin of the DUT 40. The power switch 58 produces power supplies (sources) of predetermined voltage levels which are supplied to power source pins of the DUT 40. A response output of the DUT 40 is received by the comparator 57 which compares the response output with an expected value. If the device output is mismatched with the expected value, the comparator 57 generates a failure signal. Upon receiving the failure signal, the end of test logic 55 generates an end of test signal which is provided to the host computer 22 as an interrupt through the tester bus 52. The end of test logic 55 is a subject of another patent application, U.S. application Ser. No. 09/559,365 filed Apr. 24, 2000, owned by the same assignee of this invention.

For the pin signal, pursuant to the pin configuration data from the configuration software 32, the pin configuration register 54 allows the pin driver electronics 56 to be configured for a high or low signal level (reference voltages), or for high impedance. For the DUT supply power (power sources), pursuant to the power configuration data from the configuration software 32, the power supply 36 provides the preconfigured voltage and current levels to the power switch 58. For both signal and power, trigger lines are used to quickly apply the desired configurations under software control. In this example of FIG. 5, most of the operations are applied via the tester bus 52, although this is not required.

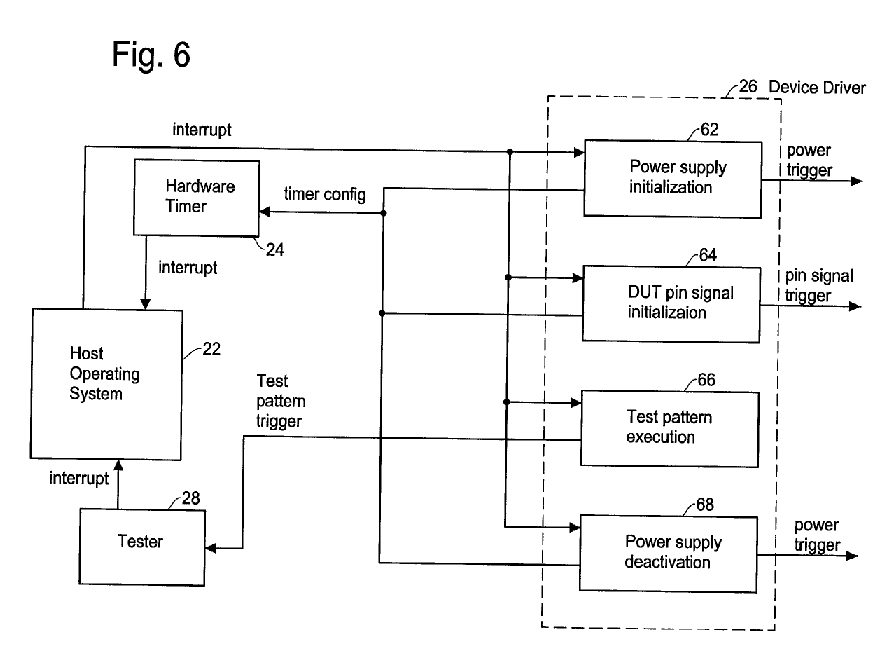

FIG. 6 shows an example of functional block diagram in the device driver 26 in the semiconductor test system of the present invention. The custom driver and hardware of the present invention are therefore designed in such way as to allow the device driver 26 to make simple and fast decisions that directly and indirectly control the tester 28. In this way, the device driver 26 is able to control the sequencing of the tester 28, without violating restrictions that the operating system makes on the device driver 26. The device driver 26 is a privileged and reconfigurable software component that can be added to a general-purpose operating system in the host computer 22. The device driver 26 is provided to respond to the associated hardware in a timely fashion. In particular, the general purpose operating system (host computer 22) enables the device driver 26 to service hardware interrupts by allowing it to execute with a minimal time latency and with high priority.

In the present invention, the device driver 26 is particularly designed to respond to the interrupts that are generated by the hardware timer 24 or by the tester hardware 28. The host computer 22 is able to respond to the interrupts from the hardware time 24 or tester hardware 28 and sends the interrupts to the device driver 26. Upon receiving the interrupt, the device driver immediately produces a trigger signal for activating a power configuration or signal configuration noted above in the hardware control circuitry 34.

In the example of FIG. 6, the device driver 26 includes a power supply initialization unit 62, a DUT pin signal initialization unit 64, a test pattern execution unit 66, and a power supply deactivation unit 68. Based on the configuration and timing data, the power supply initialization unit 62 sends a power trigger to the hardware control circuitry 34 to set the predetermined power supplies (sources) for the DUT. Similarly, based on the configuration and timing data, the DUT pin signal initialization unit 64 sends a pin signal trigger to the hardware control circuitry 34 to set the pin signal (high and low reference voltage levels or high impedance). In response to the interrupt, the test pattern execution unit 66 sends a test pattern trigger to generate the test pattern by the tester 28 which is supplied to the DUT. At the end of the test, the power supply deactivation unit 68 produces a power trigger to deactivate the power supply to the DUT.

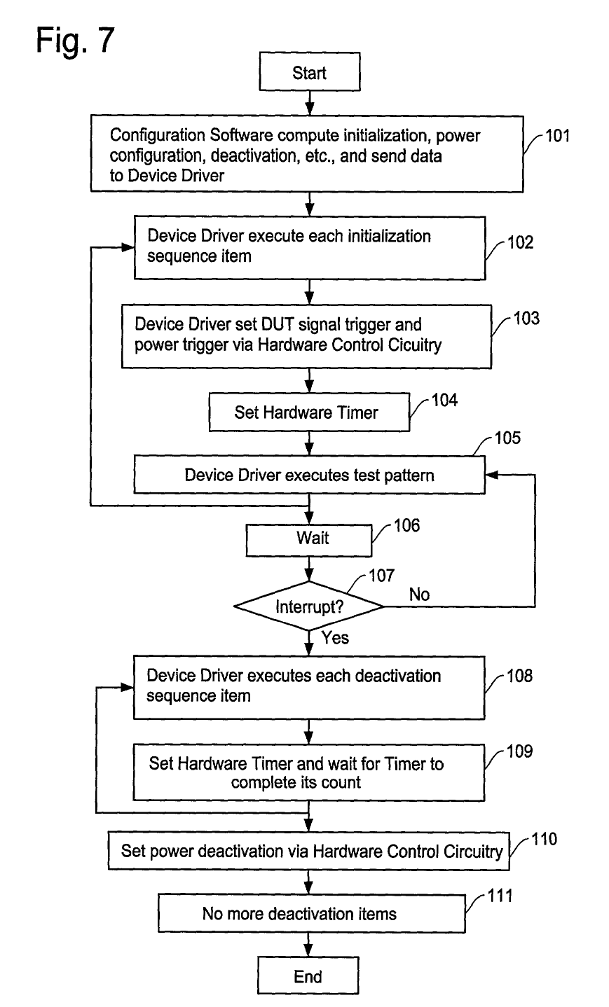

An example of operation in the semiconductor test system in the test start and end sequence is shown in the flow chart of FIG. 7. As noted above, the test program is provided to the configuration software 32 from the host computer 22. Before the start of the test, at step 101, the configuration software 32 computes the initialization timing, power and signal configuration, deactivation timing, and etc. Based on the computation, the configuration software 32 creates consolidated test sequence and sends the test sequence data to the device driver 26.

In step 102, the device driver 26 executes each initialization sequence item (e.g., power source configuration and timing, test signal configuration and timing, and test pattern start timing). The device driver 26 sets one of the initialization items, such as the DUT pin signal trigger or the power trigger via the hardware control circuitry 34 at step 103. Upon receiving the power trigger, for example, the hardware control circuitry 34 operates the switches to supply the power sources configured based on the power configuration data from the configuration software 32. Similarly, upon receiving the power trigger, the hardware control circuitry 34 operates the switches to set the reference voltages (such as high, low and high impedance) for the test pattern. Therefore, the timings of the power sources for the DUT 40 and the references levels of the test pattern are controlled by the device driver 26.

The device driver 26 also sends a timer trigger and timer configuration data to the hardware timer 24 at step 104. Thus, the hardware timer 24 measures a time length specified by the configuration data from the device driver 26 and produces an interrupt at the specified time. The interrupt is sent to the host computer 22 which immediately transmits the interrupt to the device driver 26. Thus, at step 105, in response to the interrupt, the device driver 26 executes the test pattern which is supplied to the DUT 40. Accordingly, the initialization timings are accurately regulated by the timing critical device driver 26. Further, the start timing of the test pattern to the DUT 40 relative to the other initialization items is accurately controlled in the semiconductor test system.

The foregoing process involving the steps 102-105 may be repeated for applying test patterns to the DUT in various parameters, for example, different power supply voltages, different test signal reference voltages, and etc. Thus, during step 106, the semiconductor test system continues testing the DUT while waiting for an end of test signal is generated by the hardware tester 28.

In step 107, it is determined whether an interrupt is issued by the tester 28. Such an interrupt is produced when the end of test logic 55 in FIG. 5 generates an end of test signal. Typically, an end of test signal is generated when the response output of the DUT 40 is inconsistent with the expected data at the comparator 57. Upon receiving the interrupt based on the end of test signal, at step 108, the device driver 26 executes the deactivation sequence item to control the timings involving the end of the test. The device driver 26 stops executing the test pattern so that the test pattern ends at the specified timing.

The device driver 26 sends a timer trigger and timer configuration data to the hardware timer 24 at step 109 to produced an interrupt which determines the timing of deactivating the power sources to the DUT 40. The device driver 26 waits for the hardware timer 24 to complete counting the specified time length. The hardware timer 24 produces an interrupt at the timing specified by the timer configuration data from the device driver 26. The interrupt returns to the device driver 26 through the host computer 22. Thus, the device driver 26 sends a power trigger to the hardware control circuitry 34 to disconnect the power sources from the DUT at step 110. The deactivation process involving the steps 108-110 may be repeated if there are other deactivation items. Thus, if it is confirmed that no more deactivation items exist at step 111, the process ends. In this manner, the time critical test sequence is performed with use of the general purpose operating system.

As has been described above, according to the present invention, the semiconductor test system is able to produce timing critical test sequence without using a specialized real time operating system. Since the semiconductor test system uses a general purpose operating system, flexibility, serviceability and abundance of application software are available. The semiconductor test system achieves the timing critical sequence in activating and deactivating various parameters for each test by incorporating the combination of custom hardware and software.

Although only a preferred embodiment is specifically illustrated and described herein, it will be appreciated that many modifications and variations of the present invention are possible in light of the above teachings and within the purview of the appended claims without departing the spirit and intended scope of the invention.

What is claimed is:

1. A semiconductor test system for testing semiconductor devices, comprising:
a tester hardware for providing power sources to power source pins of a semiconductor device under test (DUT) and applying a test pattern to an input pin of the DUT and evaluating an output signal of the DUT;
a host computer operated by a general purpose operating system for controlling an overall operation of the semiconductor test system based on a test program;
a configuration software for computing configuration data indicating configuration of the power sources and reference voltages of the test pattern and timing data indicating timings of activating and deactivating the power sources, reference voltages and test pattern, the configuration software computing the configuration data and timing data based on the test program prior to testing the DUT;
a device driver for providing a power trigger and a signal trigger to the tester hardware to trigger the timings of activating and deactivating the power sources and the reference voltages in the hardware tester; and
a hardware timer for producing an interrupt signal after a predetermined time defined by the device driver and sending the interrupt signal to the device driver through the host computer;
wherein the device driver causes to start the test pattern upon receiving the interrupt signal from the hardware timer and to deactivate the power sources to the DUT upon receiving the interrupt signal from the hardware timer.

2. A semiconductor test system as defined in claim 1, wherein the device driver causes to stop the test pattern upon receiving an end of test signal generated by the tester hardware through the host computer and triggers the hardware timer to produce an interrupt signal after a specified time interval and causes to deactivate the power sources to the DUT upon receiving the interrupt signal from the hardware timer.

3. A semiconductor test system as defined in claim 1, wherein the device driver is a software configured to respond to the interrupt signal through the host computer in a timely fashion with a minimal time latency and with high priority.

4. A semiconductor test system as defined in claim 1, wherein the device driver is designed to respond to the interrupt signal generated by the hardware timer or an interrupt signal generated by the tester hardware.

5. A semiconductor test system as defined in claim 1, wherein the tester hardware includes a hardware control circuitry for formatting the test pattern based on the reference voltages defined by the configuration data from the configuration software and for forming the power sources for the DUT defined by the configuration data from the configuration software.

6. A semiconductor test system as defined in claim 5, wherein the tester hardware further includes a comparator for comparing the output signal of the DUT with an expected signal and producing a failure signal when detecting mismatch between the output signal and the expected signal, and an end of test logic for producing an end of test signal when receiving the failure signal from the comparator.

7. A semiconductor test system as defined in claim 6, wherein the host computer produces an interrupt signal upon receiving the end of test signal from the tester hardware and provides the interrupt signal to the device driver.

8. A semiconductor test system for testing semiconductor devices, comprising:
a tester hardware for providing power sources to power source pins of a semiconductor device under test (DUT) and applying a test pattern to an input pin of the DUT and evaluating an output signal of the DUT;
a host computer operated by a general purpose operating system for controlling an overall operation of the semiconductor test system based on a test program;
means for computing configuration data indicating configuration of the power sources and reference voltages of the test pattern and timing data indicating timings of activating and deactivating the power sources, reference voltages, and test pattern wherein the configuration data and timing data are determined based on the test program prior to testing the DUT;
means for providing a power trigger and a signal trigger to the tester hardware to trigger the timings of activating and deactivating the power sources and the reference voltages in the hardware tester; and
a hardware timer for producing an interrupt signal after a predetermined time defined by the providing means and sending the interrupt signal to the providing means through the host computer;
wherein the test pattern is started upon receiving the interrupt signal from the hardware timer and the power sources to the DUT is deactivated upon receiving the interrupt signal from the hardware timer.

9. A semiconductor test system as defined in claim 8, wherein the test pattern ends upon receiving an end of test signal generated by the tester hardware, and the hardware timer produces an interrupt signal at a specified time after the end of test signal, and the power sources to the DUT are deactivated immediately after the interrupt signal from the hardware timer.

10. A semiconductor test system as defined in claim 8, wherein the tester hardware includes a hardware control circuitry for formatting the test pattern based on the reference voltages defined by the configuration data determined by the computing means and for forming the power sources for the DUT defined by the configuration data determined by the computing means.

11. A semiconductor test system as defined in claim 8, wherein the tester hardware further includes a comparator for comparing the output signal of the DUT with an expected signal and producing a failure signal when detecting mismatch between the output signal and the expected signal, and an end of test logic for producing an end of test signal when receiving the failure signal from the comparator.

12. A semiconductor test system as defined in claim 8, wherein the host computer produces an interrupt signal upon receiving the end of test signal from the tester hardware.
